(19) United States
(12) Patent Application Publication
(10) Pub. No.: US 2011/0265847 A1
(43) Pub. Date: Nov. 3, 2011

(54) THIN-FILM SOLAR CELL MODULE AND MANUFACTURING METHOD THEREOF

(75) Inventors: Yu-Chun Peng, Tainan City (TW); Chih-Hsiung Chang, Tainan City (TW); Yi-Kai Lin, Tainan City (TW); Chen-Liang Liao, Tainan City (TW)

(73) Assignee: AURIA SOLAR CO., LTD., Tainan City (TW)

(21) Appl. No.: 13/180,892

(22) Filed: Jul. 12, 2011

(30) Foreign Application Priority Data
May 13, 2011 (TW) 100116928

(51) Int. Cl. H01L 31/05; H01L 31/0224

(52) U.S. Cl. 136/244; 438/80; 257/E31.124

(57) ABSTRACT

A thin-film solar cell module includes a substrate, a plurality of thin-film solar cells, a first ribbon, and a second ribbon. The thin-film solar cells are disposed on the substrate in a first direction, and the thin-film solar cell module has an isolation zone between the two thin-film solar cells next to each other. Each of the thin-film solar cells includes a first electrode layer, a photoelectric conversion layer, and a second electrode layer, in which the photoelectric conversion layer and the second electrode layer are disposed on the first electrode layer with a portion of the first electrode layer exposed. The first ribbon is used for connecting the exposed portion of the first electrode layer in each of the thin-film solar cells, and the second ribbon is used for connecting each of the second electrode layers.

### CROSS-REFERENCE TO RELATED APPLICATIONS

This non-provisional application claims priority under 35 U.S.C. §119(a) on Patent Application No(s). 100116928 filed in Taiwan, R.O.C. on May 13, 2011, the entire contents of which are hereby incorporated by reference.

### BACKGROUND

1.Technical Field

The present invention relates to a solar cell module and a method for manufacturing thereof, and more particularly to a thin-film solar cell module and a method for manufacturing thereof.

2. Related Art

According to different substrates, solar cells can be classified into wafer-based solar cells (referred to as wafer solar cells hereinafter) and thin-film-type solar cells (referred to as thin-film solar cells hereinafter). Although the wafer solar cell has better photoelectric conversion efficiency than the thin-film solar cell does, the substrate of the wafer solar cell is inflexible and larger, so that the wafer solar cell is not easily popularized and applied in practical use. Moreover, the manufacturing cost of the thin-film solar cell is lower than that of the wafer solar cell (the manufacturing cost of amorphous silicon is lower than that of monocrystalline silicon or polycrystalline silicon), so the development of the thin-film solar cell attracts much attention from the industry.

A solar cell module includes solar cells. The operating voltage of a solar cell module composed of wafer solar cells is about 42 voltages (V), and the operating voltage of a solar cell module composed of thin-film solar cells is about 130 to 180 V. Due to the high operating voltage of the solar cells mentioned before, such solar cell modules need connect with conversion elements in series during the installation of a photovoltaic array system so as to be utilized in practical use.

### SUMMARY

The disclosure relates to a thin-film solar cell module and a method for manufacturing thereof, so as to solve the problems in the prior art.

According to an embodiment, a thin-film solar cell module comprises a substrate, thin-film solar cells, a first ribbon, and a second ribbon. Each of the thin-film solar cells is disposed on the substrate in a first direction, and the thin-film solar cell module has an isolation zone between two of the thin-film solar cells next to each other. Each of the thin-film solar cells comprises a first electrode layer, a photoelectric conversion layer, and a second electrode layer. The photoelectric conversion layer and the second electrode layer are disposed on the first electrode layer with a portion of the first electrode layer exposed. The first ribbon is used for connecting the exposed portion of the first electrode layer in each of the thin-film solar cells, and the second ribbon is used for connecting each of the second electrode layers.

An embodiment discloses a method for manufacturing a thin-film solar cell module, which comprises: forming a first electrode layer on a substrate; forming at least one photoelectric conversion layer and a second electrode layer on the first electrode layer, and a portion of the first electrode layer being not covered by the at least one photoelectric conversion layer and the second electrode layer; performing a cutting process to form thin-film solar cells, in which the thin-film solar cell module has an isolation zone between two of the thin-film solar cells next to each other; connecting the exposed portion of the first electrode layer not covered by the at least one photoelectric conversion layer and the second electrode layer in each of the thin-film solar cells by a first ribbon; and connecting each of the second electrode layers by a second ribbon.

According to the embodiments, the thin-film solar cells are connected in parallel. Due to the design, on the one hand, a thin-film solar cell module with low operating voltage benefits the installation of a photovoltaic array system. On the other hand, because each of the thin-film solar cells in the thin-film solar cell module has better voltage matching, the thin-film solar cell module does not have any current limiting effect. Moreover, while the thin-film solar cell module according to the embodiment is shadowed, the thin-film solar cell module does not have the shadow effect substantially. Furthermore, the cutting process only needs to perform only once to achieve the purpose in the method for manufacturing the thin-film solar cell module, such that the method for manufacturing the thin-film solar cell module is simplified, and the thin-film solar cell module has more photoelectric conversion areas, and therefore, the economic benefit of the thin-film solar cell module is increased.

### BRIEF DESCRIPTION OF THE DRAWINGS

The present invention will become more fully understood from the detailed description given herein below for illustration only, and thus are not limitative of the present invention, and wherein:

FIG. 1 is a perspective view of an embodiment of a thin-film solar cell module from a first angle of view;

FIG. 2 is a perspective view of the thin-film solar cell module in FIG. 1 from a second angle of view;

FIG. 3 is a fabrication flow chart of the thin-film solar cell module in FIG. 1;

FIG. 4 is a flow chart of an embodiment of Step 308 in FIG. 3;

FIG. 5 is a side view of an embodiment of the thin-film solar cell module in Steps 402, 404, and 406;

FIG. 6 is a flow chart of an embodiment of Step 310 in FIG. 3; and

FIG. 7 is a side view of an embodiment of the thin-film solar cell module in Steps 502, 504, and 506.

### DETAILED DESCRIPTION

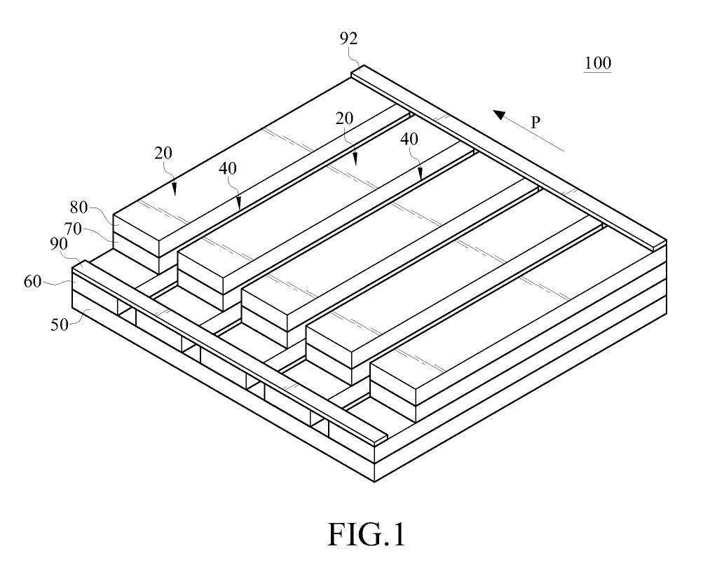

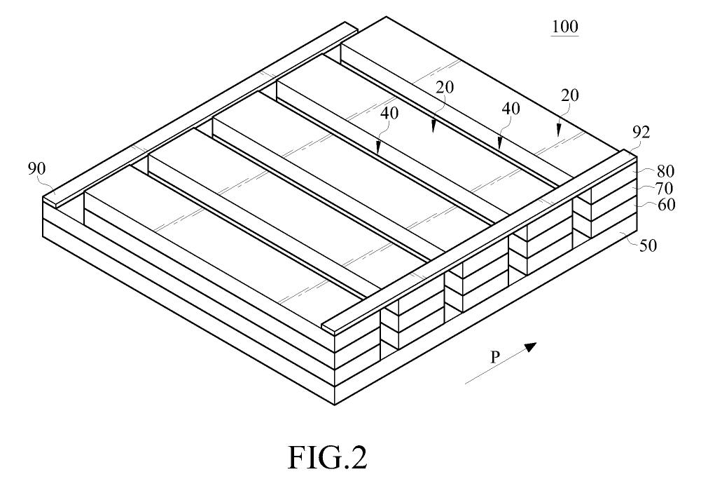

FIG. 1 is a perspective view of an embodiment of a thin-film solar cell module from a first angle of view and FIG. 2 is a perspective view of the thin-film solar cell module in FIG. 1 from a second angle of view. As shown in FIGS. 1 and 2, the thin-film solar cell module 100 comprises a substrate 50, five thin-film solar cells 20, a first ribbon 90, and a second ribbon 92. In this embodiment, the number of the thin-film solar cells 20 is five, but this embodiment does not intend to limit the present invention. The number of the thin-film solar cells 20 may be adjusted according to the actual requirements.

The thin-film solar cells 20 are disposed on the substrate 50 in a first direction P, and the thin-film solar cell module 100 has an isolation zone 40 between the two thin-film solar cells 20 next to each other. Each of the thin-film solar cells 20 comprises a first electrode layer 60, a photoelectric conversion layer 70, and a second electrode layer 80. The photoelectric conversion layer 70 and the second electrode layer 80 are disposed on the first electrode layer 60 with a portion of the first electrode layer 60 exposed. The first ribbon 90 is used for connecting the exposed portion of the first electrode layer 60 in each of the thin-film solar cells 20, and the second ribbon 92 is used for connecting each of the second electrode layers 80. In this embodiment, the number of the photoelectric conversion layer 70 may be one, and the material of the photoelectric conversion layer 70 may be amorphous silicon, but this embodiment does not intend to limit the present invention. This is to say, the number of the photoelectric conversion layers 70 may also be two (that is, a tandem thin-film solar cell), and the material of one of the photoelectric conversion layers 70 may be amorphous silicon and the material of the other photoelectric conversion layers 70 may be microcrystalline silicon.

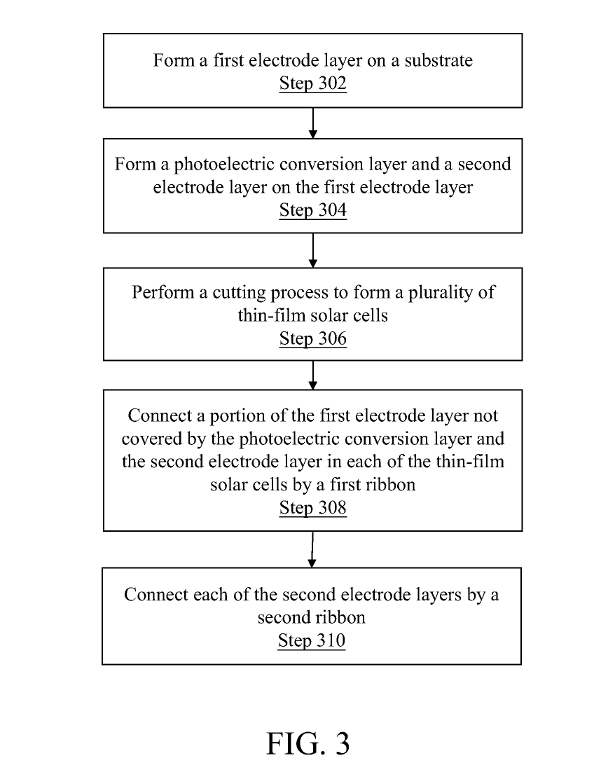

FIG. 3 is a fabrication flow chart of an embodiment for fabricating the thin-film solar cell module in FIGS. 1 and 2. As shown in FIGS. 1, 2, and 3, the method for fabricating the thin-film solar cell module 100 comprises the following steps.

In Step 302, a first electrode layer is formed on a substrate.

In Step 304, a photoelectric conversion layer and a second electrode layer are formed on the first electrode layer, and a portion of the first electrode layer is not covered by the photoelectric conversion layer and the second electrode layer.

In Step 306, a cutting process is performed to form thin-film solar cells, and the thin-film solar cell module has an isolation zone between the two thin-film solar cells next to each other.

In Step 308, the exposed portion of the first electrode layer not covered by the photoelectric conversion layer and the second electrode layer in each of the thin-film solar cells is connected by a first ribbon.

In Step 310, each of the second electrode layers is connected by a second ribbon.

In Step 302, the material of the substrate 50 may be, but not limited to, anti-reflection glass substrate. The material of the first electrode layer 60 may be, but not limited to, Transparent Conducting Oxide (TCO), and in some embodiments, the material of the TCO thin film may be, but not limited to, Indium Tin Oxide (ITO), Indium Sesquioxide (In₂O₃), Tin Dioxide (SnO₂), Zinc Oxide (ZnO), Cadmium Oxide (CdO), Aluminum doped Zinc Oxide (AZO) or Indium Zinc Oxide (IZO). The method for forming the first electrode layer 60 on the substrate 50 may be, but not limited to, Electron Beam Evaporation, Physical Vapor Deposition or sputtering deposition, and may be adjusted according to the actual properties of the first electrode layer 60.

In Step 304, the method for forming the photoelectric conversion layer 70 on the first electrode layer 60 may be, but not limited to, Chemical Vapor Deposition (CVD). In some embodiments, the CVD may be, but not limited to, Radio Frequency Plasma Enhanced Chemical Vapor Deposition (RF PECVD), Very High Frequency Plasma Enhanced Chemical Vapor Deposition (VHF PECVD) or Microwave Plasma Enhanced Chemical Vapor Deposition (MW PECVD). The material of the second electrode layer 80 may be, but not limited to, TCO or metal, and the material of the metal layer may be, but not limited to, silver or aluminum. The method for forming the second electrode layer 80 on the photoelectric conversion layer 70 may be, but not limited to, Electron Beam Evaporation, Physical Vapor Deposition or Sputtering Deposition, and may be adjusted according to the actual properties of the second electrode layer 80.

When the photoelectric conversion layer 70 and the second electrode layer 80 are formed on the first electrode layer 60, a method for shadowing a portion of the first electrode layer 60 with a mask may be used for the portion of the first electrode layer 60 avoiding being covered by the photoelectric conversion layer 70 and the second electrode layer 80, but this embodiment does not intend to limit the present invention. That is to say, after the photoelectric conversion layer 70 and the second electrode layer 80 fully cover the first electrode layer 60, a method of laser cutting or etching may be used for enabling a portion of the originally-covered first electrode layer 60 to be exposed. The cutting process in Step 306 may be laser cutting or etching.

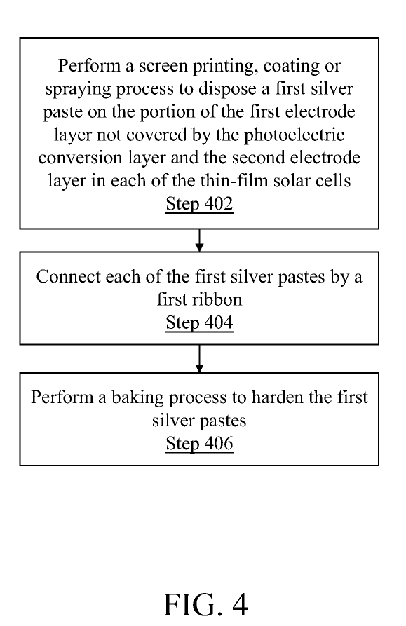

The first ribbon 90 in Step 308 may be, but not limited to, a copper wire or an aluminum wire wrapped with an alloy of solver and tin. FIG. 4 is a flow chart of an embodiment of Step 308 in FIG. 3. A method for connecting the exposed portion of the first electrode layer 60 not covered by the photoelectric conversion layer 70 and the second electrode layer 80 in each of the thin-film solar cells 20 by the first ribbon 90 comprises the following steps.

In Step 402, first silver pastes are disposed on the portion of a first electrode layer not covered by a photoelectric conversion layer and a second electrode layer in each of thin-film solar cells by screen printing, coating or spraying.

In Step 404, each of the first silver pastes is connected by a first ribbon.

In Step 406, the first silver pastes are hardened by baking.

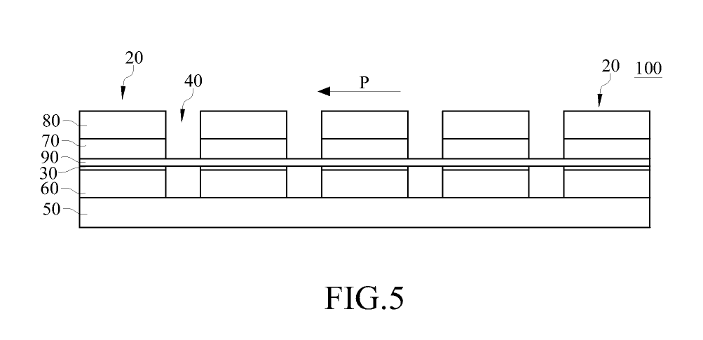

Therefore, in Steps 402, 404, and 406, the first ribbon 90 connects the exposed portions of the first electrode layers 60 not covered by the photoelectric conversion layer 70 and the second electrode layer 80 in each of the thin-film solar cells 20 by the first silver pastes 30 (FIG. 5 is a side view of an embodiment of the thin-film solar cell module in Steps 402, 404, and 406), but this embodiment does not intend to limit the present invention. That is to say, the first ribbon 90 may also connect the exposed portions of the first electrode layers 60 not covered by the photoelectric conversion layer 70 and the second electrode layer 80 in each of the thin-film solar cells 20 by welding.

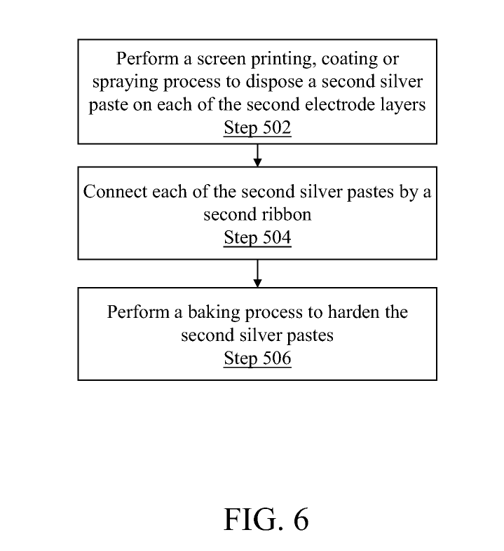

The second ribbon 92 in Step 310 may be, but not limited to, a copper wire or an aluminum wire wrapped with an alloy of silver and tin. FIG. 6 is a flow chart of an embodiment of Step 310 in FIG. 3. A method for connecting each of the second electrode layers 80 by second ribbon 92 comprises the following steps.

In Step 502, second silver pastes are disposed on second electrode layers by screen printing, coating or spraying, so that each of the second electrode layers has one paste.

In Step 504, each of the second silver pastes is connected by a second ribbon.

In Step 506, the second silver pastes are hardened by baking.

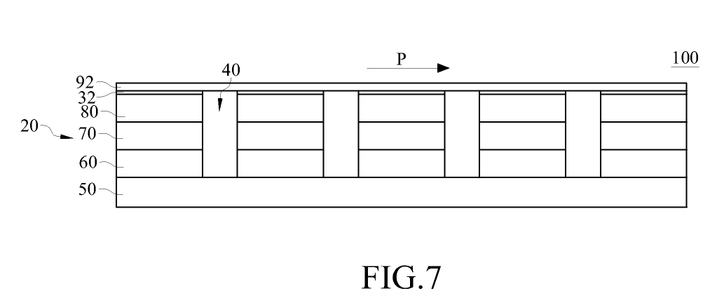

Therefore, in Steps 502, 504, and 506, the second ribbon 92 connects each of the second electrode layers 80 by the second silver pastes (FIG. 7 is a side view of an embodiment of the thin-film solar cell module in Steps 502, 504, and 506), but this embodiment is not intended to limit the present invention. That is to say, the second ribbon 92 may also connect each of the second electrode layers 80 by welding.

In this embodiment, the baking processes in Steps 406 and 506 may be performed sequentially, but this embodiment is not intended to limit the present invention. That is to say, the baking processes in Steps 406 and 506 may be performed simultaneously (that is, after Steps 404 and 504 are performed, the baking process is performed to harden the first silver pastes 30 and the second silver pastes 32 at the same time).

According to an embodiment of the present invention discloses the design of the plurality of thin-film solar cells connected in parallel. Due to the design, on one hand, a solar cell module with low operating voltage benefits the installation of a photovoltaic array system, and the voltage of the solar cell module correlates to the properties of the photoelectric conversion layer of each of the solar cells. On the other hand, as the solar cell module has better voltage matching, the solar cell module does not have the current limiting effect due to the different performances of each of the solar cells. When the solar cell module of the embodiment is shadowed, since the solar cells are connected in parallel, the solar cell module substantially does not have a shadow effect. Moreover, the cutting process only needs to perform only once to achieve the purpose in the method for manufacturing the thin-film solar cell module, so that the process is simplified, and the solar cell module has more photoelectric conversion areas. Therefore, the economic benefit of the solar cell module is increased.

What is claimed is:

1. A thin-film solar cell module, comprising:
a substrate;
a plurality of thin-film solar cells, disposed on the substrate in a first direction, wherein an isolation zone is between two of the thin-film solar cells next to each other, each of the thin-film solar cells comprises a first electrode layer, a photoelectric conversion layer, a second electrode layer, and the photoelectric conversion layer and the second electrode layer are disposed on the first electrode layer with a portion of the first electrode layer exposed;
a first ribbon, for connecting the exposed portion of the first electrode layer in each of the thin-film solar cells; and
a second ribbon, for connecting each of the second electrode layers.

2. The thin-film solar cell module as claimed in claim 1, wherein the first ribbon connects the exposed portion of the first electrode layer in each of the thin-film solar cells by a first silver paste.

3. The thin-film solar cell module as claimed in claim 1, wherein the second ribbon connects each of the second electrode layers by a second silver paste.

4. A method for manufacturing a thin-film solar cell module, comprising:
forming a first electrode layer on a substrate;
forming at least one photoelectric conversion layer and a second electrode layer on the first electrode layer, wherein a portion of the first electrode layer is not covered by the at least one photoelectric conversion layer and the second electrode layer;
performing a cutting process to form a plurality of thin-film solar cells, wherein the thin-film solar cell module has an isolation zone between two thin-film solar cells next to each other;
connecting the portion of the first electrode layer not covered by the at least one photoelectric conversion layer and the second electrode layer in each of the thin-film solar cells by a first ribbon; and
connecting each of the second electrode layers by a second ribbon.

5. The method for manufacturing the thin-film solar cell module as claimed in claim 4, wherein the cutting process is laser cutting or etching.

6. The method for the thin-film solar cell module according to claim 4, wherein the steps of connecting the portion of the first electrode layer not covered by the at least one photoelectric conversion layer and the second electrode layer in each of the thin-film solar cells by the first ribbon comprises:
performing a screen printing, coating or spraying process to dispose a first silver paste on the portion of the first electrode layer not covered by the at least one photoelectric conversion layer and the second electrode layer in each of the thin-film solar cells;
connecting each of the first silver pastes by the first ribbon; and
performing a baking process to harden the first silver pastes.

7. The method for manufacturing the thin-film solar cell module as claimed in claim 4, wherein the steps of connecting each of the second electrode layers by the second ribbon comprises:
performing a screen printing, coating or spraying process to dispose a second silver paste on each of a plurality of second electrode layers;
connecting each of the second silver pastes by a second ribbon; and
performing a baking process to harden the second silver pastes.
